(19) United States
(12) Patent Application Publication
(10) Pub. No.: US 2005/0045804 A1
(43) Pub. Date: Mar. 3, 2005

(54) Pixel of CMOS image sensor using phototransistor

(75) Inventors: Young June Park, Seoul (KR); Youn Jae Kook, Seoul (KR)

Correspondence Address: NIXON & VANDERHYE, PC, 1100 N GLEBE ROAD, 8TH FLOOR, ARLINGTON, VA, 22201-4714, US

(73) Assignee: Seoul National University Industry Foundation, Seoul (KR)

(21) Appl. No.: 10/787,739

(22) Filed: Feb. 27, 2004

(30) Foreign Application Priority Data
Aug. 28, 2003 (KR) 2003-59827

(51) Int. Cl. H01L 27/00

(52) U.S. Cl. 250/208.1

(57) ABSTRACT

Provided is a pixel of a CMOS image sensor using a phototransistor. The pixel includes the phototransistor, a selection transistor, and a reset transistor. The phototransistor senses externally applied light and generates charges. The selection transistor outputs corresponding charges stored in the phototransistor in response to a selection signal. The reset transistor sends a base of the phototransistor to a reset voltage level in response to a reset signal. The pixel further includes an integrator having a positive input terminal to which a predetermined set voltage is applied and a negative input terminal which is connected to a first terminal of the selection transistor. The integrator includes a switch which connects or disconnects the negative input terminal and an output terminal of the integrator in response to an integrator control signal.

### BACKGROUND OF THE INVENTION

This application claims the priority of Korean Patent Application No. 2003-59827 filed on Aug. 28, 2003, in the Korean Intellectual Property Office, the disclosure of which is incorporated herein in its entirety by reference.

### FIELD OF THE INVENTION

The present invention relates to a complementary metal-oxide semiconductor (CMOS) image sensor, and more particularly, to a pixel of a CMOS image sensor using a phototransistor.

### DESCRIPTION OF THE RELATED ART

In general, an image sensor is classified into a charge coupled device (CCD) image sensor and a CMOS image sensor.

The CCD image sensor comprises an sensing unit, which is usually composed of photodiodes, transmitting unit and output unit. Photocharges at each photodiode are transmitted to the output unit.

Traditionally, the CCD image sensor has been prevailed in image sensor applications. The CCD image sensor, however, is fabricated with a complex process and requires high voltage and high power compared with the CMOS image sensor. On the contrary, the CMOS image sensor, which became famous recently, has strong advantage that can be fabricated with CMOS process. Therefore, the CMOS image sensor is easy to be integrated with other CMOS circuits and relatively speaking, requires low voltage and low power.

FIG. 1 is a circuit diagram of a conventional pixel of a CMOS image sensor.

The pixel 100 of the CMOS image sensor comprises a photo-diode PD and four transistors TR1, TR2, TR3, and TR4. The reset transistor TR2 resets the gate node of the driving transistor TR3 in response to a reset signal RX. The selection transistor TR4 outputs a reset voltage in response to a selection signal SX.

The selection transistor TR4 and the reset transistor TR2 are turned off and the transmission transistor TR1 is turned on in response to a transmission control signal TX such that photocharges accumulated in the photo-diode PD are transmitted to the gate of the driving transistor TR3. As photocharges accumulated in the photo-diode PD become more, the voltage level of the gate of the driving transistor TR3 becomes lower.

If the selection transistor TR4 is turned on again in response to the selection signal SX, a voltage corresponding to the amount of the photocharges accumulated in the photo-diode PD is output. The CMOS image sensor reads the voltage corresponding to the amount of the photocharges accumulated in the photo-diode and the reset voltage, compares the two values, and outputs their difference as an electrical signal.

However, the pixel size has been scaled down using the advanced CMOS process and the operational voltage has been reduced to implement a large pixel array. With a decrease in the pixel size, the amount of photocurrent is reduced.

To minimize a reduction in the amount of photocurrent, a method of using a phototransistor instead of a photo-diode has been proposed. In this method, photogenerated electrons and holes pairs are amplified using the phototransistor and an amplified signal is output. However, in this method using a phototransistor, not only an output signal but also noise are amplified. Also, the phototransistor cannot be used in the low light intensity condition.

### SUMMARY OF THE INVENTION

The present invention provides a pixel of a CMOS image sensor using a phototransistor.

In accordance with an aspect of the present invention, there is provided a pixel of a CMOS image sensor comprising a phototransistor, a selection transistor, and a reset transistor.

The phototransistor senses externally applied light and generates charges. The selection transistor outputs corresponding charges stored in the phototransistor in response to a selection signal. The reset transistor sends a base of the phototransistor to a reset voltage level in response to a reset signal.

The pixel further comprises an integrator having a positive input terminal to which a predetermined set voltage is applied and a negative input terminal which is connected to a first terminal of the selection transistor. The integrator comprises a switch which connects or disconnects the negative input terminal and an output terminal of the integrator in response to an integrator control signal.

The phototransistor comprises a vertical PNP-type bipolar junction transistor (BJT) which includes a P-type substrate, an N-type well, and a P-type region disposed within the N-type well; and a lateral PNP-type BJT which includes the N-type well and two P-type regions disposed within the N-type well. The phototransistor is a PMOS transistor in which the gate and the N-type well are tied to operate as the base.

The lateral PNP-type BJT is structured such that the gate surrounds an emitter and a collector surrounds the gate. The selection transistor is an NMOS transistor having the first terminal which is connected to the negative input terminal of the integrator and a second terminal which is connected to the emitter of the phototransistor. The reset transistor has a first terminal which is connected to the base of the phototransistor and a second terminal which is connected to a reset voltage.

When the integrator control signal is activated to a high level, the integrator and the phototransistor are reset. When the integrator control signal is inactivated to a low level, a voltage level corresponding to a reset state of the phototransistor is read or a voltage level corresponding to the amount of charges stored in the phototransistor is read.

In accordance with another aspect of the present invention, there is provided a pixel of a CMOS image sensor comprising a phototransistor, a first PMOS transistor, and a second PMOS transistor.

The phototransistor senses externally applied light and generates charges.

The first PMOS transistor has a gate to which a selection signal is applied and a first terminal which is connected to an emitter of the phototransistor. The first PMOS transistor outputs charges stored in the phototransistor or receives charges externally to transmit the charges to the phototransistor.

The second PMOS transistor has a gate to which a reset signal is applied, a first terminal which is connected to a base of the phototransistor, and a second terminal which is connected to a reset voltage. The second PMOS transistor sends the base of the phototransistor to a reset voltage level.

The phototransistor has a triple well structure in which an N-type well is formed on a P-type substrate and a P-type well is formed on the N-type well. The phototransistor comprises a vertical NPN-type BJT which includes an N-type region disposed within the P-type well and the N-type well; and a lateral NPN-type BJT which includes the P-type well and two N-type regions disposed within the P-type well. Also, the phototransistor is an NMOS transistor in which a gate and the P-type well of the phototransistor are tied to operate as the base.

### BRIEF DESCRIPTION OF THE DRAWINGS

The above features and advantages of the present invention will become more apparent by describing in detail exemplary embodiments thereof with reference to the attached drawings in which:

FIG. 1 is a circuit diagram of a conventional pixel of a CMOS image sensor;

FIG. 2A is a circuit diagram of a pixel of a CMOS image sensor according to an embodiment of the present invention;

FIG. 2B is a timing diagram illustrating the operations of the pixel shown in FIG. 2A;

FIG. 3 is a sectional view of the pixel shown in FIG. 2A;

FIG. 4 is a conceptual diagram illustrating a method of tying a gate and a body shown in FIG. 3;

FIG. 5A is a circuit diagram of a pixel of a CMOS image sensor according to another embodiment of the present invention;

FIG. 5B is a timing diagram illustrating the operations of the pixel shown in FIG. 5A; and

FIG. 6 is a sectional view of the pixel shown in FIG. 5A.

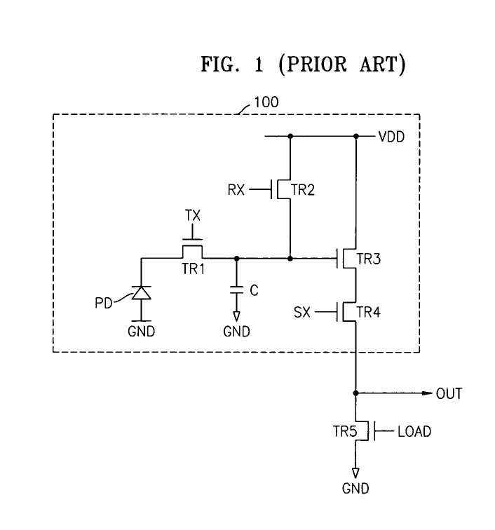

### DETAILED DESCRIPTION OF THE INVENTION

The present invention will now be described more fully with reference to the accompanying drawings, in which preferred embodiments of the invention are shown. The same reference numerals in different drawings represent the same element.

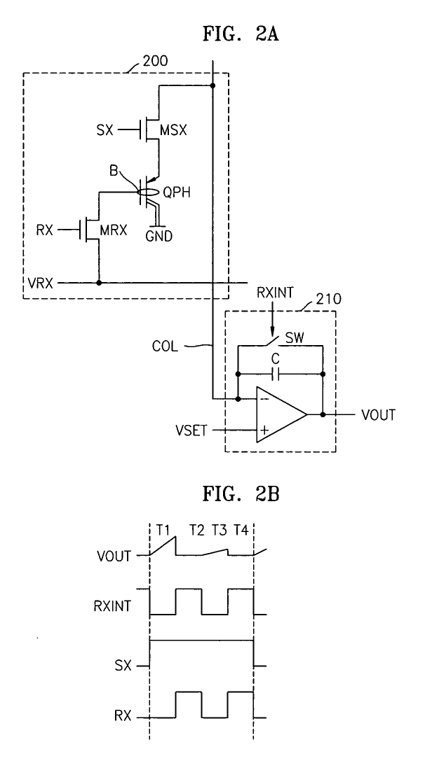

FIG. 2A is a circuit diagram of a pixel of a CMOS image sensor according to an embodiment of the present invention.

FIG. 2B is a timing diagram illustrating the operations of the pixel shown in FIG. 2A.

Referring to FIG. 2A, the pixel 200 of the CMOS image sensor according to the embodiment of the present invention comprises a phototransistor QPH, a selection transistor MSX, and a reset transistor MRX.

The phototransistor QPH senses externally applied light and generates charges. The selection transistor MSX outputs charges stored in the phototransistor QPH in response to a selection signal SX. Alternatively, the selection transistor MSX receives charges externally and transmits the charges to the phototransistor QPH.

The reset transistor MRX sends the base B of the phototransistor QPH to a reset voltage level in response to a reset signal RX.

The pixel 200 of the CMOS image sensor comprises a phototransistor QPH, a selection transistor MSX, and a reset transistor MRX and operates in response to the selection signal SX and the reset signal RX.

The reset voltage VRX is a voltage required for resetting the base B of the phototransistor QPH. The output current of the pixel 200 is output as an output voltage VOUT through an integrator 210, which is connected to the first terminal COL of the selection transistor MSX.

The pixel 200 can be manufactured by a CMOS process and uses a PMOS transistor, in which a gate and a body are tied to operate as a base B, as the phototransistor QPH. Since the phototransistor QPH is composed of lateral and vertical BJT structures, a large photocurrent can be output even in the low light intensity condition.

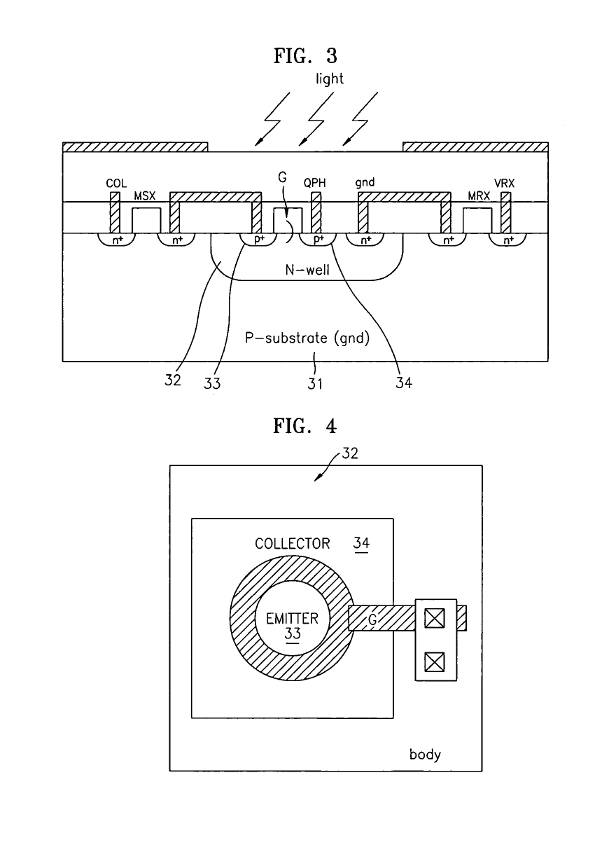

The structure of the phototransistor QPH will be described in more detail with reference to FIG. 3.

FIG. 3 is a sectional view of the pixel 200 shown in FIG. 2A.

The phototransistor QPH is a PMOS transistor in which the gate G and a body 32 are tied to operate as the base B. This phototransistor QPH operates as a PNP-type BJT. A detailed description thereof is disclosed in Korean Patent Laid-open Publication No. 2002-0021735.

To illustrate the gate G and the body 32, which are tied to operate as the base B, the base B is illustrated as an ellipse that ties the gate G and the body in FIG. 2.

The phototransistor QPH comprises a lateral PNP-type BJT and a vertical PNP-type BJT. The vertical PNP-type BJT is composed of a P-type substrate 31, an N-type well 32, and a P-type region 33 disposed within the N-type well 32.

The lateral PNP-type BJT is composed of the N-type well 32 and two P-type regions 33 and 34 disposed within the N-type well 32. The phototransistor QPH is a PMOS transistor in which the gate G and the N-type well 32 (i.e., the body) are tied to operate as the base B.

Since this phototransistor QPH uses the vertical and lateral BJTs, it can output a large photocurrent even in the low light condition.

The pixel 200 of the CMOS image sensor further comprises an integrator 210. A predetermined set voltage VSET is applied to a positive input terminal of the integrator 210, and a first terminal of the selection transistor MSX is connected to a negative input terminal thereof. The integrator 210 comprises a switch SW, which connects or disconnects the negative input terminal and an output terminal of the integrator 210 in response to an integrator control signal RXINT.

The selection transistor MSX is an NMOS transistor. A negative input terminal of the integrator 210 is connected to a first terminal COL of the selection transistor MSX, and an emitter of the phototransistor QPH is connected to a second terminal thereof. The reset transistor MRX is an NMOS transistor. The base B of the phototransistor QPH is connected to a first terminal of the reset transistor MRX, and the reset voltage VRX is connected to a second terminal thereof.

The operations of the pixel 200 of the CMOS image sensor will be described with reference to FIG. 2B.

After the selection transistor MSX is turned on in response to the selection signal SX, the pixel 200 enters on the following four phases of T1, T2, T3, and T4 to output a photocurrent and a reset voltage.

If electrons are accumulated in the N-well 32 of the phototransistor QPH by externally applied light, the voltage level of the N-well 32 becomes gradually low and the voltage level of the emitter 33 also becomes gradually low.

During T1, just as the selection signal SX is activated to a high level, the selection transistor MSX is turned on. Then, the integrator 210 instantaneously holds the voltage level of the emitter 33 of the phototransistor QPH to a set voltage VSET. If the selection signal SX is held at the high level, an output voltage VOUT of the integrator 210 is output at a voltage level, which is proportional to a reduction in voltage level of the N-well 32 due to the externally applied light.

That is, the phototransistor QPH senses externally applied light and outputs a signal value, which is defined by the voltage change during T1.

During T2, if the integrator control signal RXINT and the reset signal RX are activated at a high level, the switch SW connects the negative input terminal and the output terminal such that the integrator 210 is reset, and the reset transistor MRX is turned on such that a voltage of the base B of the phototransistor QPH is reset to a reset voltage VRX. Here, the integrator 210 holds a voltage of the emitter 33 of the phototransistor QPH at the set voltage VSET.

While the voltage of the base B and the voltage of the emitter 33 in the phototransistor QPH are being reset to certain voltage levels, i.e., the levels of the reset voltage VRX and the set voltage VSET, respectively, the pixel 200 that has received the previous light is reset so as to receive the next light.

During T3, if the integrator control signal RXINT and the reset signal RX are activated at a low level, an output voltage VOUT of the integrator 210 is output at the voltage level of the pixel 200 that is reset during T2. That is, this output voltage VOUT of the integrator 210 is a reference value that is obtained when the phototransistor QPH is reset.

During T4, if the integrator control signal RXINT and the reset signal RX are activated at a high level, the pixel 200 is reset again. After T4, if the integrator control signal RXINT and the reset signal RX are inactivated to a low level, the phototransistor QPH is floated and senses applied light. Thus, the voltage levels of the N-well 32 and the emitter 33 are varied.

After the signal value and the reference value are obtained from the phases T1, T2, T3, and T4, their difference can be used as light intensity in a signal processing circuit (not shown), which receives the output voltage VOUT of the integrator 210.

When the pixel 200 is reset, the voltage level of the base B is reset to the reset voltage VRX and the voltage level of the emitter 33 is reset to the set voltage VSET of the integrator 210. Here, the levels of the reset voltage VRX and the set voltage VSET are determined such that a slight forward voltage is caused between the base B and the emitter 33 of the phototransistor QPH. That is, the level of the reset voltage VRX is determined to be lower by approximately 0.3 to 0.4 V than that of the set voltage VSET.

In this reset condition, since the phototransistor QPH can operate avoiding the low current region, the signal value and the reference value can be obtained irrespective of noise.

FIG. 4 is a conceptual diagram illustrating a method of tying a gate and a body shown in FIG. 3.

In the phototransistor QPH shown in FIG. 3, the lateral PNP-type BJT is constructed such that the gate G surrounds the emitter 33, and the collector 34 surrounds the gate G.

To maximize the influence of the lateral PNP-type BJT on the phototransistor QPH, as shown in FIG. 4, the gate G is formed in a closed curve shape. While the inside of the closed curve is used as the emitter 33, the outside thereof is used as the lateral collector 34.

In this structure, the width of the gate G can be increased in a limited area so as to maximize the influence of the lateral PNP-type BJT on the phototransistor QPH. Also, the area of the collector 34 may be larger than that of the emitter 33 so as to increase the photogeneration of electrons and holes between the base 32 and the collector 34.

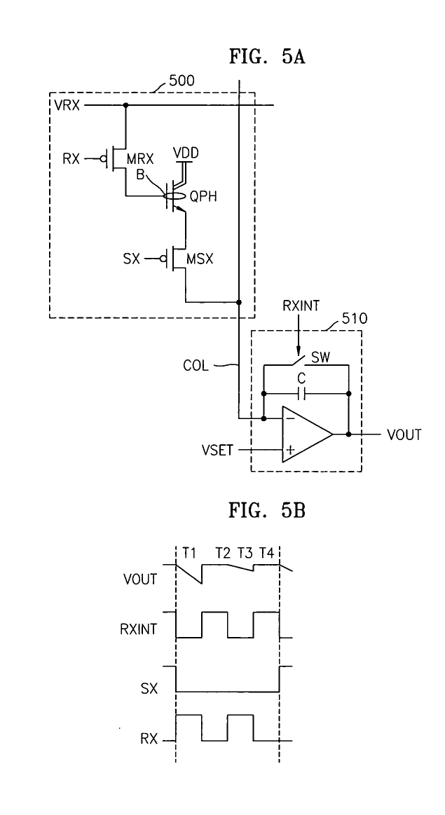

FIG. 5A is a circuit diagram of a pixel of a CMOS image sensor according to another embodiment of the present invention.

FIG. 5B is a timing diagram illustrating the operations of the pixel shown in FIG. 5A.

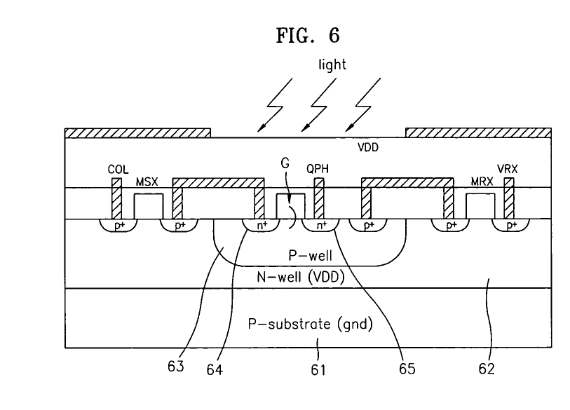

FIG. 6 is a sectional view of the pixel shown in FIG. 5A.

The pixel 500 of the CMOS image sensor according to another embodiment of the present invention comprises a phototransistor QPH, a first PMOS transistor MSX, and a second PMOS transistor MRX.

The phototransistor QPH senses externally applied light and generates charges. A selection signal SX is applied to the gate of the first PMOS transistor MSX and the emitter of the phototransistor QPH is connected to a first terminal thereof. Thus, the first PMOS transistor outputs charges stored in the phototransistor QPH. Alternatively, the first PMOS transistor receives charges externally to transmit the charges to the phototransistor QPH.

A reset signal RX is applied to the gate of the second PMOS transistor MRX. Also, the base B of the phototransistor QPH is connected to a first terminal of the second PMOS transistor MRX, and the reset voltage VRX is connected to a second terminal thereof. Thus, the base B of the phototransistor QPH is sent to a level of the reset voltage VRX.

The pixel 500 shown in FIG. 5A comprises different types of transistors from the pixel 200 shown in FIG. 2A but it operates on the same operation principles as the pixel 200.

While the selection transistor MSX and the reset transistor MRX of FIG. 2A are NMOS transistors, the first PMOS transistor MSX and the second PMOS transistor MRX of FIG. 5A are PMOS transistors. Also, the phototransistor QPH of FIG. 2A has a PMOS transistor structure but the phototransistor QPH of FIG. 5A has an NMOS transistor structure.

More specifically, the phototransistor QPH of FIG. 5A has a tripe well structure in which an n-well well 62 is formed on a P-type substrate 61 and a P-type well 63 is formed on the n-well 62.

The phototransistor QPH of FIG. 5A comprises a vertical NPN-type BJT and a lateral NPN-type BJT. The vertical NPN-type BJT comprises the N-type well 62, the P-type well 63, and an N-type well 64 disposed within the P-type well 63. The lateral NPN-type BJT comprises the P-type well 63 and two N-type wells 64 and 65 disposed within the P-type well 63.

As shown in FIG. 6, the phototransistor QPH is an NMOS transistor in which the gate G and the P-type well 63 are tied to operate as the base B.

As shown in the timing diagram shown in FIG. 5B, the pixel 500 enters on four phases T1, T2, T3, and T4 to repeat read and reset operations. Also, after signal value and reference value are obtained, their difference can be used as light intensity in a signal processing circuit, which receives the output voltage VOUT of the integrator 210.

When the phototransistor QPH of FIG. 5A is reset, a forward voltage is caused between the base B and the emitter of the phototransistor QPH. Since the pixel 500 shown in FIG. 5A operates on the same operation principles as the pixel 200 of FIG. 2A, a detailed description of its operations will be omitted here.

The pixels 200 and 500 of the present invention each operate using a new phototransistor QPH, thereby enabling generation of a large photocurrent in a low-intensity light condition, and can be manufactured by a CMOS process.

Also, the structures and the operation methods of the pixels 200 and 500 are adequate for the manufacture of a CMOS image sensor. In particular, the states of the pixels 200 and 500 can be reset and the reset values thereof can be read, thus enabling correlated double sampling (CDS) operations. The pixels 200 and 500 use the CDS operations, where the difference between the signal value and the reference value is used to minimize the fixed pattern noise (FPN) caused by process variations in each pixel.

As described above, the pixel of the CMOS image sensor of the present invention can obtain a large photocurrent even in the low light intensity condition by using a gate-body tied phototransistor. Also, the pixel can read a reset value of the phototransistor and thus enables CDS operations, where the output of photogenerated electrons and holes is read and the difference between the reset value and an output value is obtained. Further, the phototransistor can be reset avoiding the low current region that is susceptible to noise. Thus, the CMOS image sensor is not susceptible to the noise and ensures the improved image quality.

In the drawings and specification, there has been disclosed a typical preferred embodiment of the invention and, although, specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

1. A pixel of a CMOS image sensor comprising:
a phototransistor which senses externally applied light and generates charges;
a selection transistor which outputs corresponding charges stored in the phototransistor in response to a selection signal; and
a reset transistor which sends the base of the phototransistor to a reset voltage level in response to a reset signal.

2. The pixel of claim 1, further comprising an integrator having a positive input terminal to which a predetermined set voltage is applied and a negative input terminal which is connected to a first terminal of the selection transistor,
wherein the integrator comprises a switch which connects or disconnects the negative input terminal and an output terminal of the integrator in response to an integrator control signal.

3. The pixel of claim 2, wherein the phototransistor comprises:
a vertical PNP-type bipolar junction transistor which includes a P-type substrate, an N-type well, and a P-type region disposed within the N-type well; and
a lateral PNP-type bipolar junction transistor which includes the N-type well and two P-type regions disposed within the N-type well,
wherein the phototransistor is a PMOS transistor in which the gate and the N-type well are tied to operate as the base.

4. The pixel of claim 3, wherein the lateral PNP-type bipolar junction transistor is structured such that the gate surrounds an emitter and a collector surrounds the gate.

5. The pixel of claim 3, wherein the selection transistor is an NMOS transistor having the first terminal which is connected to the negative input terminal of the integrator and a second terminal which is connected to the emitter of the phototransistor.

6. The pixel of claim 3, wherein the reset transistor having a first terminal which is connected to the base of the phototransistor and a second terminal which is connected to a reset voltage.

7. The pixel of claim 3, wherein when the phototransistor is reset, a forward voltage is caused between the base and the emitter of the phototransistor.

8. The pixel of claim 2, wherein when the integrator control signal is activated to a high level, the integrator and the phototransistor are reset,
and when the integrator control signal is inactivated to a low level, a voltage level corresponding to a reset state of the phototransistor is read or a voltage level corresponding to the amount of charges stored in the phototransistor is read.

9. A pixel of a CMOS image sensor comprising:
a phototransistor which senses externally applied light and generates charges;
a first PMOS transistor having a gate to which a selection signal is applied and a first terminal which is connected to an emitter of the phototransistor, the first PMOS transistor which outputs corresponding charges stored in the phototransistor; and
a second PMOS transistor having a gate to which a reset signal is applied, a first terminal which is connected to a base of the phototransistor, and a second terminal which is connected to a reset voltage, the second PMOS transistor which sends the base of the phototransistor to a reset voltage level.

10. The pixel of claim 9, further comprising an integrator having a positive input terminal to which a predetermined set voltage is applied and a negative input terminal which is connected to a second terminal of the first PMOS transistor,
wherein the integrator comprises a switch which connects or disconnects the negative input terminal and an output terminal of the integrator in response to an integrator control signal.

11. The pixel of claim 10, wherein the phototransistor has a triple well structure in which an N-type well is formed on a P-type substrate and a P-type well is formed on the N-type well,
wherein the phototransistor comprises:
a vertical NPN-type bipolar junction transistor which includes an N-type region disposed within the P-type well and the N-type well; and
a lateral NPN-type bipolar junction transistor which includes the P-type well and two N-type regions disposed within the P-type well,
and wherein the phototransistor is an NMOS transistor in which a gate and the P-type well of the phototransistor are tied to operate as the base.

12. The pixel of claim 11, wherein the lateral NPN-type bipolar junction transistor is structured such that a gate surrounds an emitter and a collector surrounds the gate.

13. The pixel of claim 11, wherein when the phototransistor is reset, a forward voltage is caused between the gate and an emitter of the phototransistor.

14. The pixel of claim 10, wherein when the integrator control signal is activated to a high level, the integrator and the phototransistor are reset,
and when the integrator control signal is inactivated to a low level, a voltage level corresponding to a reset state of the phototransistor is read or a voltage level corresponding to the amount of charges stored in the phototransistor is read.
